(19) United States
(12) Patent Application Publication
(10) Pub. No.: US 2009/0092906 A1
(43) Pub. Date: Apr. 9, 2009

(54) Method of manufacturing phase shift photomask

(75) Inventor: Masahito Hiroshima, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC.,, Tokyo (JP)

(21) Appl. No.: 12/245,442

(22) Filed: Oct. 3, 2008

(30) Foreign Application Priority Data
Oct. 5, 2007 (JP) 2007-261586

(51) Int. Cl. G03F 1/00

(52) U.S. Cl. 430/5

(57) ABSTRACT

In the case where the amount of variation in dimension of a made photomask exceeds an allowable range, a glass portion of the photomask is partially subjected to etching so that a dimension of a transcribed pattern obtained when a pattern formed on the photomask is transcribed on a wafer substrate falls into the allowable range in all drawing regions.

This application is based upon and claims the benefit of priority from Japanese patent application No. 2007-261586, filed Oct. 5, 2007, the disclosure of which is incorporated herein in its entirety by reference.

### BACKGROUND OF THE INVENTION

The present invention relates to a method of manufacturing a phase shift photomask that is to be utilized to manufacture a semiconductor apparatus.

In a lithography process to be utilized to make a memory device, represented by a DRAM, it is required to faithfully transcribe all of fine LSI circuit patterns that are arranged densely into photosensitive organic material applied on a wafer. The term “faithful transcription” means that (1) a resist pattern transcribed and formed on a wafer is a shape equivalent to a design pattern image of an LSI circuit designed by a designer and has desired dimension, and further, (2) all dimensions of the formed pattern are formed in a range of allowable variation regardless of an arranged position of the pattern.

An LSI circuit pattern designed by a designer is formed on a transparent glass substrate as a monotone pattern of black and white by processing a light shielding film formed on the glass substrate by means of drawing by electron beam and a dry etching process. The light shielding film is apparent black, while the glass portion is apparent white. For this reason, the pattern is to be expressed as “monotone”, here.

When UV light with an appropriate wavelength is irradiated to a glass member (hereinafter, a photomask) in which a monotone pattern of a LSI circuit is formed by means of this light shielding film, the monotone pattern on a surface of the photomask acts as a slit. A diffraction image of light transmitted by the photomask is condensed by means of a projection optical lens of an exposure apparatus to be reduced-projected on a wafer surface that becomes an imaging point of the projector lens.

With respect to the above (1), in order to recreate a shape substantially equivalent to the design pattern image designed by the LSI designer on the wafer, it is required to heighten optical contrast in the final imaging plane to the utmost limit. In an existing exposure technology, by applying a super-resolution technology (Resolution Enhancement Technique) to obtain separation resolution of a further higher proximal pattern by means of high resolution of the exposure apparatus due to a short wavelength of an exposed light source and expansion of the number of openings in the projector lens, and a phase modulation technology (phase shift mask technology, FLEX exposure technology) in a diffractive surface of the photomask and/or a pupil plane of the projector lens, and grazing-incidence illumination to the photomask (deformed illumination technology), it meets design requirements of the LSI.

With respect to the above (2), it is a supreme proposition to ensure dimensional uniformity in an exposure area. Heretofore, by uniformizing energy distribution of an output of the light source that the exposure apparatus has, reducing lens aberration, and eliminating stray light in an exposure chamber or occurrence of contamination, deterioration in temporal properties is prevented. Further, by improving synchrony in drive systems of a wafer stage and a mask that takes on a scanning mechanism of the exposure apparatus, illumination distribution in the exposure area and distribution tendency of a focal position are improved. However, it has been seen that a ratio of an amount of variation in dimension due to a photomask pattern to the total amount of variation in dimension of the transcribed pattern reaches 30% or more, and it is the most important technology problem to improve dimensional uniformity of the photomask pattern in order to secure the dimensional uniformity at wafer transcription.

In an existing mask manufacturing scene, in order to improve dimensional uniformity of photomask patterns, efforts to improve super planarization of a blanks substrate that is a drawing target, drawing repeatable accuracy/dimensional correction accuracy of a drawing apparatus, and dimension controllability in planes of a heat treatment apparatus, a developing processing apparatus and a dry etching processing apparatus are taken.

Hereinafter, a method of manufacturing a related mask will be described with reference to FIG. 1.

A photomask (pilot mask #1) is first made in accordance with an initial condition (zero-order process condition) obtained by the efforts described above (Steps S101 to S103).

Then, in order to obtain a desired resolution performance R by means of lithography simulation for the made pilot mask #1 in accordance with Rayleigh's formula: R=k1×λ/NA, which represents a resolution performance of lithography in which the respective symbols are indicated as resolution performance: R, an exposure wavelength: λ, an opening diameter of a projector lens: NA, and a parameter indicating ease of a process: k1, optimal lithography process conditions (a lighting condition of the exposure apparatus, resist, the super-resolution technology, OPC and the like) capable of minimizing an MEEF (Mask Error Enhancement Factor) value obtained by dividing the amount of variation in dimension of the transcribed pattern by the amount of variation in dimension of the pattern on the pilot mask #1 are selected. Such a method is disclosed in Japanese Patent Application Publication No. 4-343214 and Japanese Patent Application Publication No. 2002-14459, for example.

The pattern is then transcribed on the wafer using the pilot mask #1 in accordance with the selected lithography process condition to measure dimensional distribution of the transcribed pattern (Step S104). Further, tendency of the obtained dimensional distribution is analyzed to examine whether or not it falls into a range of allowable variation in dimension under circuit characteristics of the LSI.

As a result of the examination, in the case where the amount of variation in dimension on the wafer falls into the allowable range, the pilot mask #1 is to be a regular mask. However, in many cases, the amount of variation in dimension of the pattern on the wafer made using the pilot mask #1 exceeds the allowable range. In such a case, by controlling the dimensional distribution of each of the mask drawing process, the baking process, the developing process and the etching process while the allowable range of variation in dimension of the photomask pattern is strictly set, a first-order process condition is defined so as to eliminate irregular points that will become a dimension degrading factor to make a photomask (pilot mask #2) again (Steps S121 to S123). The pattern of the pilot mask #2 is then transcribed on the wafer in the same manner as described above to measure the amount of variation in dimension of the transcribed pattern (Step S124).

Hereinafter, the above processes are repeated until the amount of variation in dimension of the transcribed pattern falls into the allowable range. In the case where the amount of variation in dimension of the transcribed pattern made using a pilot mask #n (n is a “natural number”) falls into the allowable range, it is determined that the mask pattern has predetermined dimensional uniformity, and the pilot mask #n is to be a regular mask (Steps S131 to S135).

As described above, the regular mask on which the pattern with predetermined dimensional uniformity is formed is manufactured.

FIGS. 2A to 2F show an example of measured results of the amount of variation in dimension of transcribed patterns respectively formed using a pilot mask #1, a pilot mask #i (1<i<n: “i” is a natural number) and a pilot mask #n. FIGS. 2A and 2B correspond to the pilot mask #1, FIGS. 2C and 2D correspond to the pilot mask #i, and FIGS. 2E and 2F correspond to the pilot mask #n. In this regard, FIGS. 2A, 2C and 2E are two-dimensional contour graphs respectively indicating variation tendency distribution of the transcribed patterns, while FIGS. 2B, 2D and 2F are three-dimensional contour graphs thereof.

Further, FIG. 3 is a histogram showing a distribution frequency of the amount of variation in dimension of the transcribed patterns formed by using the pilot mask #1, the pilot mask #i and the pilot mask #n based on the measured results shown in FIGS. 2A to 2F.

As can be understood from FIGS. 2A to 2F and FIG. 3, the amount of variation in dimension of the transcribed pattern reduces in the order of pilot mask #1, pilot mask #i and pilot mask #n. However, if it is assumed that a region enclosed by a broken line is an allowable range, all of the pilot masks do not meet the allowable range.

In the method of manufacturing a related photomask, it is required to make at least one piece of pilot mask until a final process condition for manufacturing a regular mask is obtained. As a matter of fact, in order to establish a photomask manufacturing process of a new product, it is required to make a few pieces or more of pilot masks. Particularly, the number of pieces of pilot masks required to obtain optimal solution of the process condition is increased as a technology level of a photomask that is required for microfabrication (fine processing) is higher.

Further, even though the final process condition to manufacture the regular mask is once obtained, it is impossible to manufacture another regular mask under the same condition in the case where accidental performance variation occurs in the manufacturing apparatus until next photomask will be manufactured. In such a case, the manufactured photomask is treated as the pilot mask, and a final process condition is obtained again by making further certain pieces of pilot masks if necessary.

As described above, in a method of manufacturing a related photomask, a plurality of pilot masks are normally made. These pilot masks are then treated as a regularly nonusable photomask because no technology to improve the dimensional uniformity exists.

The cost of manufacturing required to make a pilot mask is normally reflected to a product price of a regular mask. For this reason, the cost required to make a regular mask is increased in accordance with the number of made pilot masks.

### SUMMARY OF THE INVENTION

Therefore, the present invention seeks to obtain a method of manufacturing a photomask capable of making regular photomasks with desired dimensional uniformity without making even one pilot mask.

In an embodiment, a method of manufacturing a phase shift photomask, the method including: subjecting the photomask to additional processing so that an amount of variation in dimension of a transcribed pattern of the photomask on a wafer is in an allowable range at all drawing regions of the photomask.

According to the method of manufacturing a phase shift photomask of the present embodiment, even in the case where the amount of variation in dimension of a transcribed pattern using a photomask that has been made once does not fall into an allowable range, the amount of variation in dimension of the transcribed pattern is allowed to fall into the allowable range by subjecting the photomask to partially additional processing.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a flowchart for explaining a method of manufacturing a related photomask;

FIGS. 2A to 2F are contour graphs indicating trend distribution of variation in dimension of the pilot photomasks made by the method of manufacturing a related photomask;

FIG. 3 is a histogram indicating a frequency of variation in dimension of a plurality of pilot photomasks made by the method of manufacturing a related photomask;

FIG. 4 is a flowchart for explaining a method of manufacturing a photomask according to an embodiment of the present invention;

FIG. 5A is a schematic view showing a configuration of an exposure apparatus;

FIG. 5B is a schematic view showing a configuration of an optical microscope that imitates the exposure apparatus;

FIG. 6 is a histogram indicating a frequency of variation in dimension (before additional processing and after additional processing) of the photomasks made by the method of manufacturing a photomask according to an embodiment of the present invention;

FIGS. 7A to 7H are views for explaining a part of the steps in the flowchart of FIG. 4 in more detail;

FIG. 8 is a graph showing the amount of dimension variation of a transcribed pattern with respect to the amount of excavation in a glass portion of a photomask;

FIG. 9 is a view showing a transcribed pattern profile with respect to the amount of excavation of the glass portion of the photomask;

FIG. 10A is a partially sectional view before additional processing for the photomask; and

FIG. 10B is a partially sectional view after additional processing.

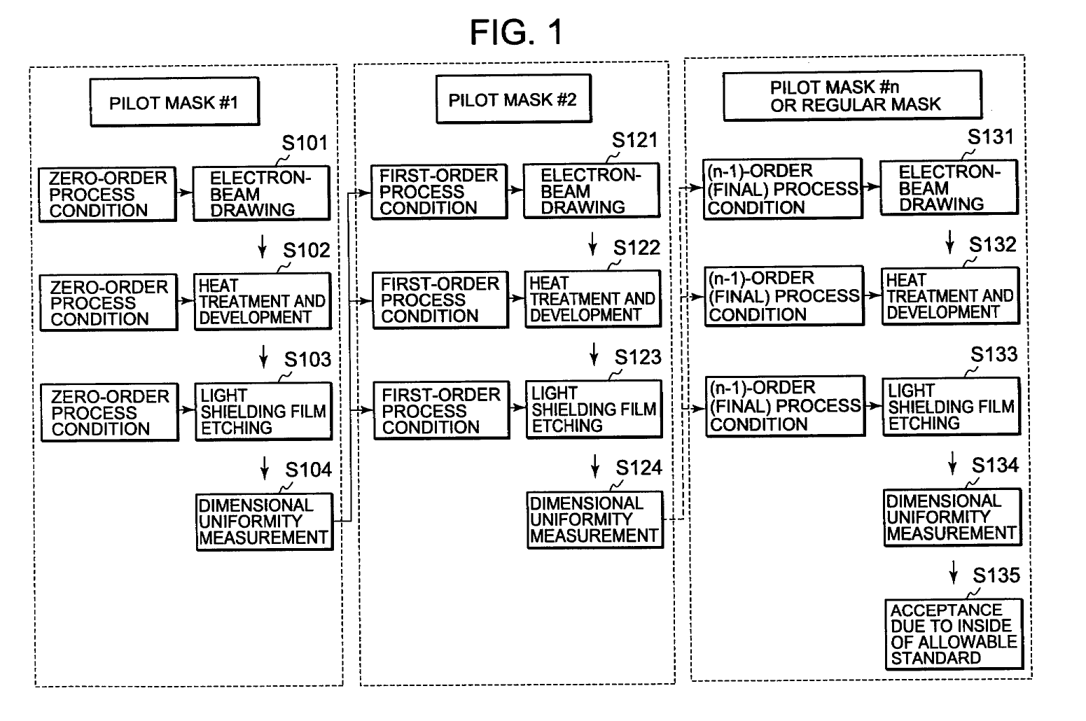

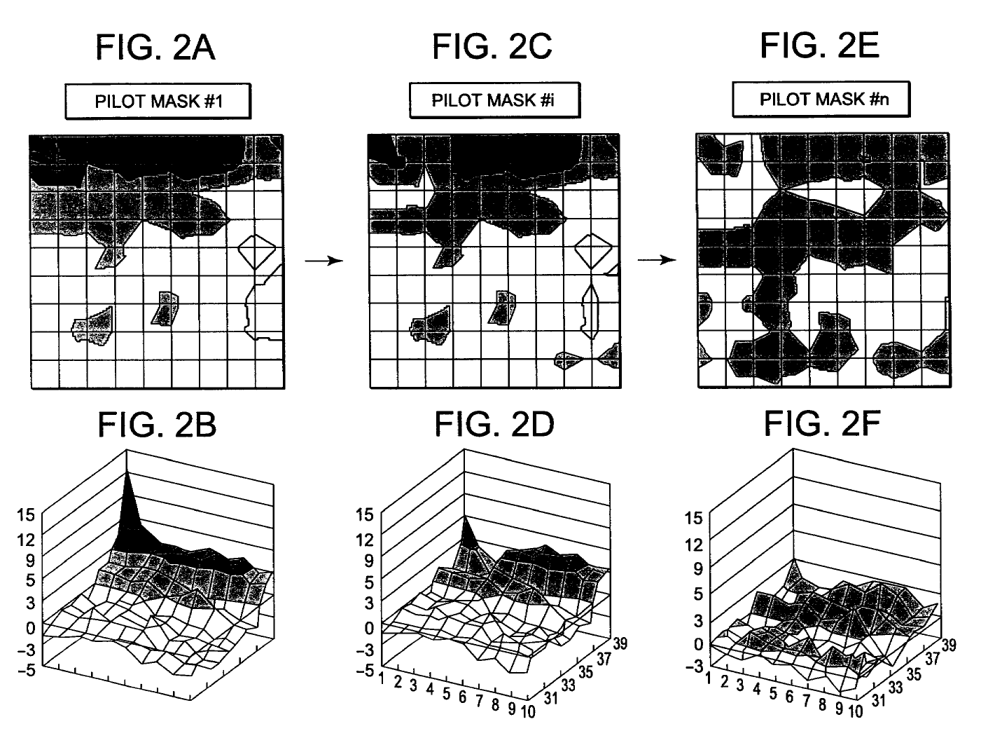

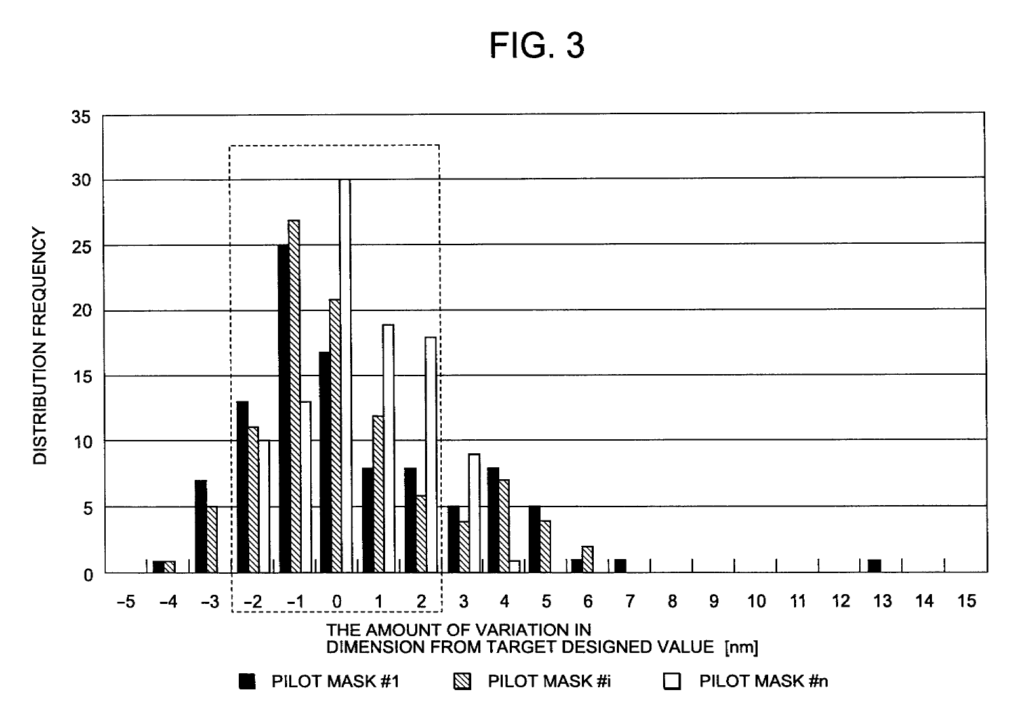

### DESCRIPTION OF THE EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The present invention is characterized in that a glass portion of a region of a photomask, which corresponds to a portion in which variation in dimension becomes apparent at transcription, is excavated by a fixed depth in the case where the amount of variation in dimension of the made photomask exceeds an allowable range. A phase difference between light transmitted by a semitransparent light shielding film and light transmitted by a glass portion locally varies by excavating the glass portion of a specific portion. As a result, an optical profile varies at a wafer transcribed position that corresponds to this portion, whereby dimensional correction so as to offset variation in dimension at wafer transcription can be carried out.

Hereinafter, embodiments of the present invention will be described in detail with reference to the drawings.

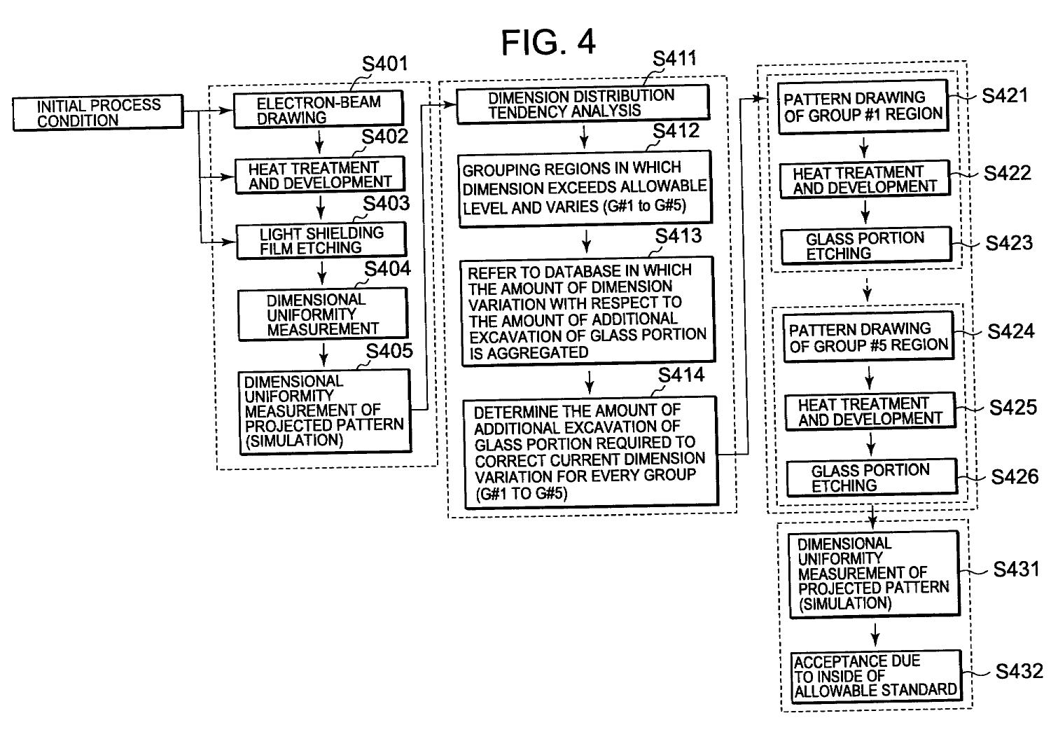

FIG. 4 shows a processing flow of a method of manufacturing a phase shift photomask according to a first embodiment of the present invention.

A raw material of a photomask that is called photomask blanks (hereinafter, referred to simply as “blanks”) is first prepared. The blanks include: a flat glass substrate having a flat surface; a semitransparent film formed by a CVD method on the surface of the flat glass substrate and having a phase shift function; and a light shielding film provided on the semitransparent film. Moreover, an organic resist film is applied and formed on the surface of the blanks. In the organic resist film, by receiving irradiation of electron beam, a property of only an irradiated portion is modified by excitation energy of electrons, and a property in which resolvability to an alkali developing fluid is different from that to other no-irradiated portion.

Next, by irradiating the surface of the blanks, that is, the organic resist film with electron beam, a predetermined pattern is drown (Step S401). Here, the predetermined pattern means, for example, a semiconductor circuit pattern such as an LSI, in particular, a pattern of a semiconductor memory or the like in which small patterns each having the same shape and the same dimension are repeatedly placed (or arranged).

Drawing is carried out by dividing a drawing region into a plurality of rectangular regions each having a predetermined size. Drawing process conditions including design data for a pattern of each divided region, arrangement information indicating a position and a size of each divided region, energy information indicating electron beam irradiation energy for each divided region and the like are inputted into a drawing apparatus as initial process conditions. The drawing apparatus then irradiates (scans) every divided region of the surface of the blanks with electron beam in accordance with the initial process conditions.

In a portion of the organic resist film that is irradiated with electron beam, a picture (latent image) of electrons is formed. In other words, in the organic resist film on the blanks surface, a property of the portion that is irradiated with electron beam is modified.

Next, the organic resist film is subjected to heat treatment and a developing process (Step S402). This developing process causes the portion of the organic resist film that has been irradiated with electron beam to dissolve (or remain), and causes the portion that has not been irradiated with electron beam to remain (or dissolve). Both positive type and negative type can be utilized as the organic resist. Thus, an organic resist pattern having a shape the same as that of an LSI circuit pattern is formed on the light shielding film.

Subsequently, a dry etching process is carried out using the organic resist pattern as an etching shielding film, whereby the light shielding film in the portion that is not coated with the organic resist film is subjected to selective excavation processing (Step S403).

In this way, a photomask is supposedly completed. That is, a pattern of the light shielding film having a shape of an LSI circuit pattern is formed on the glass substrate.

In this regard, manufacturing apparatuses respectively carrying out the heat treatment, the developing process and the dry etching process described above normally have character distribution of concentric circles in a process reaction area, and this distribution tendency is passed as dimensional distribution of the LSI circuit pattern that is arranged on the whole surface of the photomask. For this reason, revision and management of these manufacturing apparatuses and the process conditions are normally implemented in accordance with first and second procedures as follows.

First, apparatus revision is carried out in order to even character distribution of the respective manufacturing apparatuses as much as possible.

Second, nonlinear residual variation components generated in each of the manufacturing apparatuses are added each other by going through the heat treatment, developing and dry etching processes, and as a result the process conditions of the respective manufacturing apparatuses are optimized so as to be offset each other, whereby its maintenance management is carried out.

Next, pattern dimension of the made photomask is measured (Step S404). The measurement is carried out for a portion corresponding to a critical circuit pattern that contributes a device operation in design using an optical or scanning electron microscope.

In the case of a photomask for a memory device in which the same kind of pattern is arranged on the whole surface of a drawing region, variation degree of dimension (dimension difference between a pattern having a maximum dimension and a pattern having a minimum dimension, in which a dimension difference from an average dimension is most large) is calculated by measuring dimension of the pattern that is evenly sampled from all drawing regions with keeping a fixed adjacent interval without bias, and processing this statistically.

In the case where variation degree of the calculated dimension does not meet an allowable standard, the photomask is subjected to a photomask modifying process for correcting dimensional distribution tendency as follows.

An exposure process using the photomask is first simulated, whereby dimensional distribution of the pattern (transcribed pattern) transcribed (or projected) on a wafer is artificially obtained (Step S405).

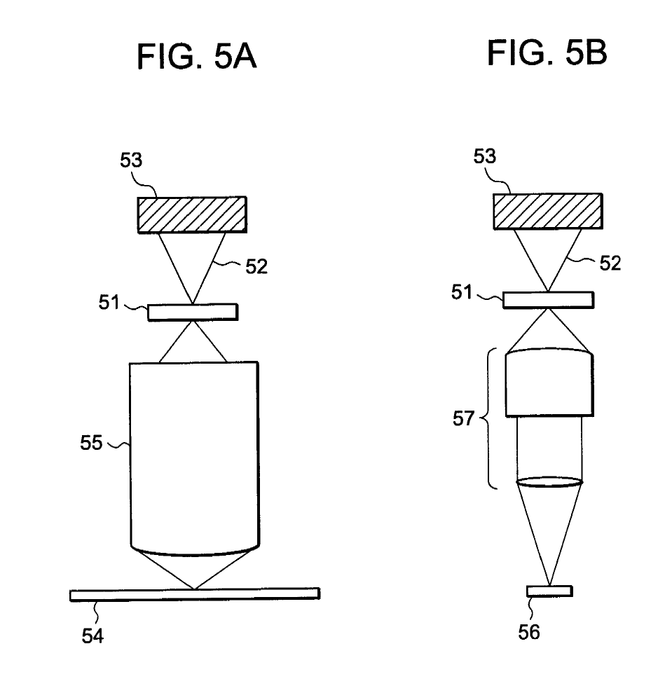

A virtual optical analysis technique can be utilized in this simulation. The “virtual optical analysis technique” may be a general optical calculation technique to virtually calculate an optical image that is subjected to reduced projection to a final imaging plane by means of a projection optical system on the basis of LSI design pattern data. Further, it may be a technique to optically calculate an optical image subjected to reduced projection on a final imaging plane on the basis of the mask pattern in which an outline portion of a pattern portion is extracted as contour data from image data in which a shape of an actual photomask pattern is photographed. Alternatively, it may be a method of observing the photomask by means of an optical microscope (Aerial Image Measurement Inspection Tool) that imitates an actual exposure apparatus, and obtaining a transcribed optical image observed in a final imaging plane of the same optical microscope. In this case, if the actual exposure apparatus includes, as shown in FIG. 5A, a lighting optical system lens unit 53 that guides exposed light 52 to a photomask 51, and a reduced projection optical system lens unit 55 that causes exposed light transmitted by the photomask 51 to be focused on a surface of a wafer 54, the optical microscope that imitates it is constructed from, as shown in FIG. 5B, a lighting optical system lens unit 53 that guides exposed light 52 to a photomask 51, a CCD light receiving element 56 that detects exposed light transmitted by the photomask 51, and an expanded-projected optical system lens unit 57 that causes the exposed light to be focused on the CCD light receiving element 56.

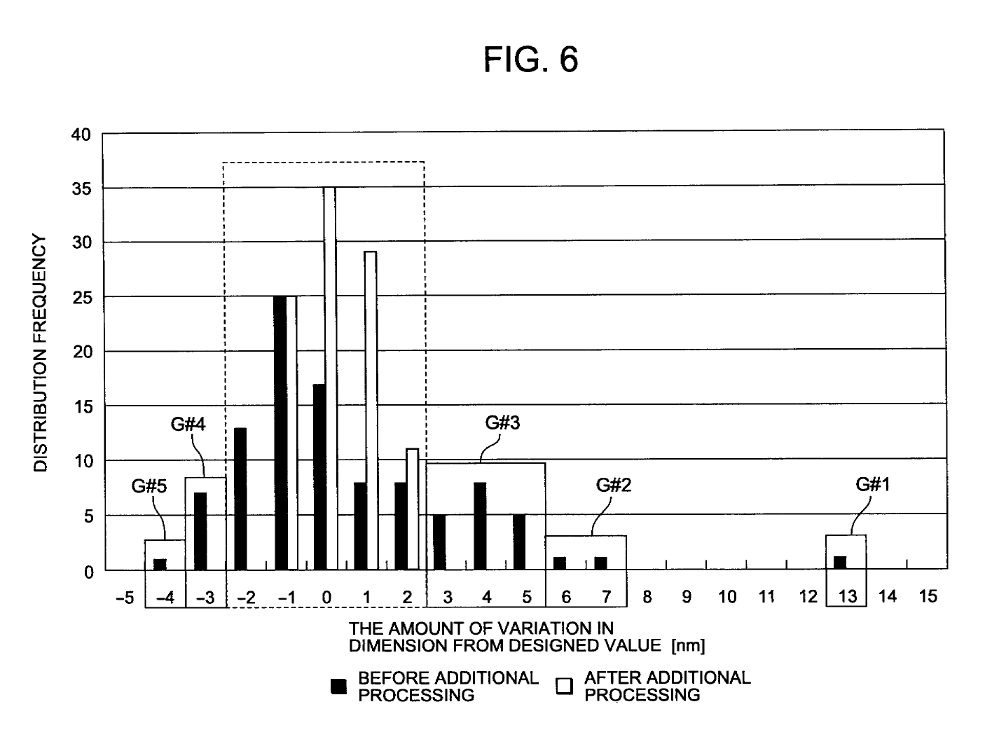

Next, dimensional distribution tendency analysis is carried out for simulation results (Step S411). Specifically, distribution frequency (black bar graph) of the amount of variation in dimension as shown in FIG. 6 is obtained from the simulation results. Grouping with respect to the amount of variation outside an allowable range shown by a broken line is then carried out in accordance with shift amounts from designed values. Here, they are divided into dimension error groups G #1 to G #5 as shown by solid lines (Step S412).

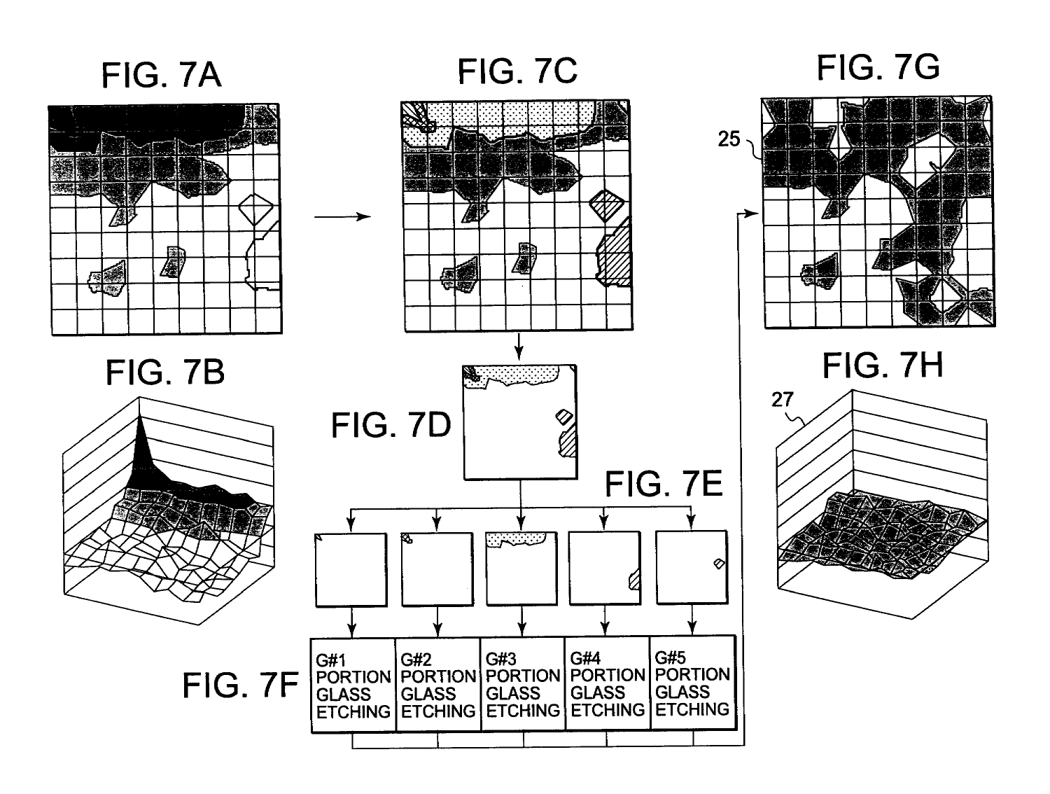

Further, in order to specify which region of the photomask variation belonging to these groups is generated in, a contour graph is created. Contours in the contour graph are those in which points each having the equal amount of variation are connected each other, and are defined so as to be capable of identifying the above groups. The contour graph becomes that as shown in FIG. 7A or 7B, for example.

Subsequently, as shown in FIG. 7C, regions in which the amount of variation in dimension is outside an allowable range are detected from the contour graph (here, the two-dimensional contour graph in FIG. 7A), and as shown in FIG. 7D, the detected regions are extracted. Moreover, as shown in FIG. 7E, the extracted regions are divided so as to be associated with each dimension error group. Thus, when the contour graphs indicating the regions respectively corresponding to the above dimension error groups G #1 to G #5 are obtained, the respective contour graphs are to be recognized as pattern data indicating regions required for processing, and they are to be drawing data for additional processing (will be described later).

Subsequently, by referring to results (that is, property data stored in a database) in which the amount of dimension variation of the transcribed pattern with respect to the amount of additional excavation (etching amount) of the glass portion of the photomask has been simulated in advance (Step S413), in each of the dimension error groups, the amount of additional excavation required to set the amount of variation in dimension to 0 is calculated (Step S414). In other words, the amount of excavation of the glass portion necessary to apply dimensional correction for offsetting the amount of variation in dimension of a wafer transcribed pattern is calculated on the basis of the property data. The property data can be calculated using a virtual optical analysis technique such as three-dimensional mask rigorous electromagnetic field simulation or an exposure emulation system.

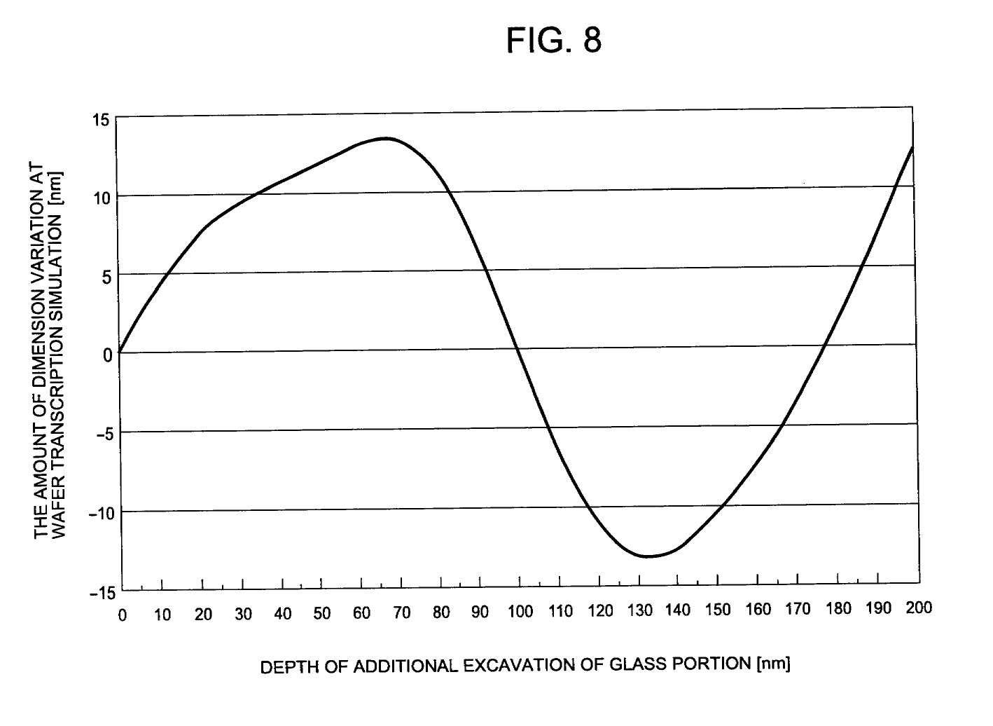

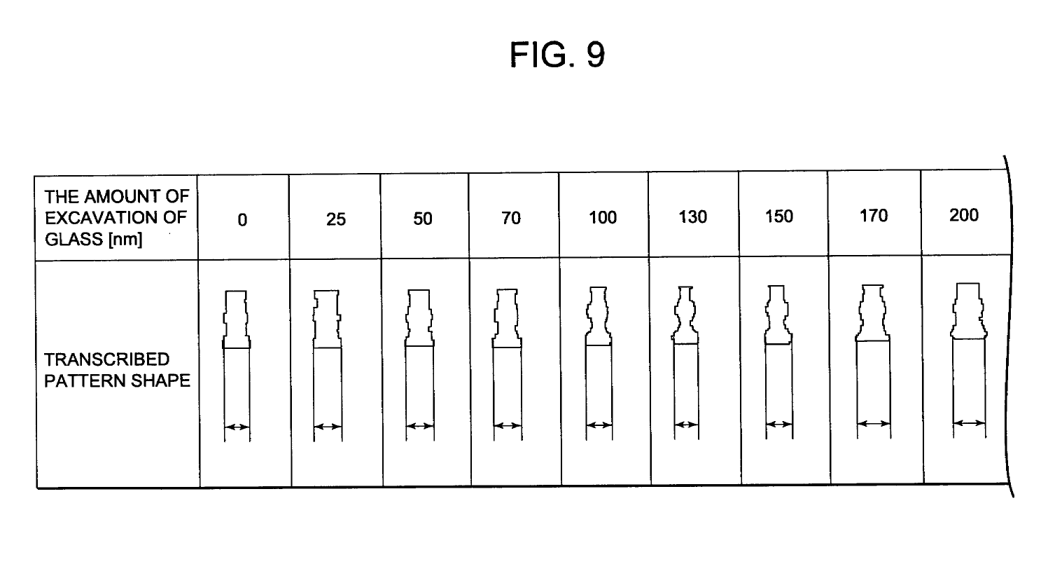

A relation as shown in FIG. 8 exists between the amount of additional excavation and the amount of dimension variation of the transcribed pattern, for example. FIG. 9 shows a relation between the amount of additional excavation based on the relation of FIG. 8 and a transcribed pattern shape.

As described above, when the region to be subjected to additional processing for the photomask and the amount of additional processing are determined, the additional processing is carried out for the respective regions in turn (Steps S421 to S426).

At first photoresist is applied to a photomask again. A pattern corresponding to the region required for processing is drawn on this photoresist in accordance with the drawing data indicating the region required for processing of the dimension error group G #1 using an electron beam or laser beam drawing apparatus (Step S421). The photoresist is then subjected to heat treatment and developed (Step S422). Thus, an opening portion corresponding to the region required for processing of the dimension error group G #1 is formed in the photoresist.

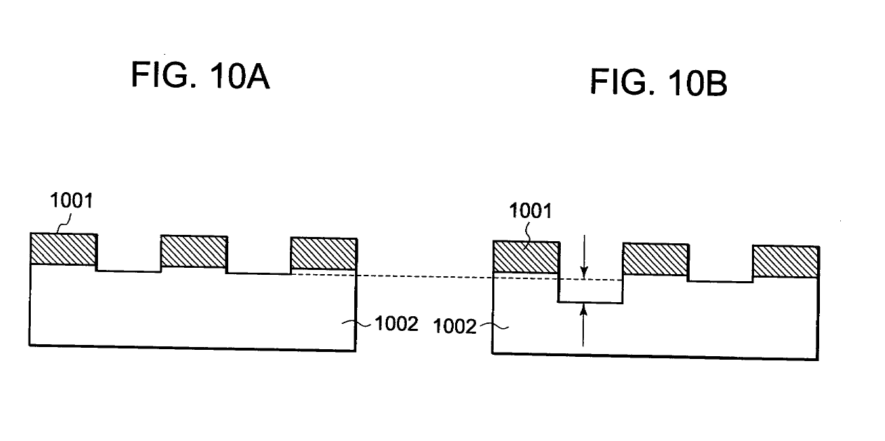

Next, the glass portion of the photomask exposed in the opening portion is subjected to etching using the resist pattern in which the opening portion is formed as an etching shielding mask. Etching conditions are defined so that the amount of excavation due to the etching becomes the amount of additional processing described above. For example, this etching allows the photomask, in which a semitransparent film 1001 with a section as shown in FIG. 10A is patterned, to become a photomask with a section as shown in FIG. 10B. Namely, a thickness of a glass portion 1002 at a specific region can be made thinner selectively.

The above process is carried out for a region required for processing of each of the remaining dimension error groups G #2 to G #5.

After the additional processing for all of the dimension error groups is completed, distribution of the amount of variation in dimension of a projected pattern is measured by means of a virtual optical analysis technique (Step S431).

When the additional processing is carried out for all of the regions required for processing of the dimension error groups G #1 to G #5 as shown in FIG. 7F, variation in dimension is reduced as shown in FIGS. 7G and 7H.

In the case where variation in dimension distribution of the projected pattern falls into the allowable range shown by the broken line as shown by the white bar graph of FIG. 6, the objected photomask is recognized as a regular product mask (Step S432).

As described above, according to the present embodiment, it is possible to manufacture a photomask in which dimension of a transcribed pattern falls into a predetermined shared range. Namely, even in the case of a photomask (pilot mask) that is destroyed as uncorrectable one because dimensional uniformity of a pattern does not meet allowable standards in the past, the additional processing allows the amount of variation in dimension of the transcribed pattern to fall into the allowable range. Therefore, the photomask can be shipped as a regular mask. Thus, according to the present embodiment, plural pieces of pilot masks that have been required in a related method of manufacturing a photomask is not necessary and large quantities of low-cost masks can be produced in a short period of time.

As described above, although the present invention has been described in view of one embodiment, the present invention is not limited to the embodiment described above and may be modified and changed without departing from the scope and spirit of the invention. For example, the present invention can be applied not only to the case of manufacturing a photomask from mask blanks, but also to correction of a photomask. Further, the present invention can also be applied to the case where variation in dimension of a transcribed pattern is generated due to an exposure apparatus to be used although the photomask is one that meets a predetermined standard. Even in such a case, by applying the present invention thereto, variation in dimension in the transcribed pattern is allowed to fall into an allowable range.

To be explained in detail, the exposure apparatus may generate variation in dimension that exceeds the allowable range in the transcribed pattern due to lens aberration or stray light, or further synchronization between reticle and a stage for supporting a wafer, luminance unevenness of illuminated light sources or the like. This type of variation in dimension is generated at a specific position (hereinafter, referred to as an irregular point of dimensional distribution) in an exposure field. On the basis of the amount of variation in dimension of this irregular point, the amount of excavation in a glass portion of the photomask required to offset this is calculated, and by excavating the glass portion in a region corresponding to the irregular point of the photomask, the amount of variation in dimension of the transcribed pattern is allowed to fall into the allowable range.

What is claimed is:

1. A method of manufacturing a phase shift photomask, the method comprising:
subjecting the photomask to additional processing so that an amount of variation in dimension of a transcribed pattern of the photomask on a wafer substrate is in an allowable range at all drawing regions of the photomask.

2. The method according to claim 1, said additional processing comprises removing a glass portion of the photomask partially by etching.

3. The method according to claim 1, wherein distribution of the amount of variation in dimension in the all drawing regions is obtained, and then a region in which the amount of variation in dimension exceeds the allowable range is specified, and said specified region of the photomask is subjected to the additional processing.

4. The method according to claim 3, wherein for obtaining the distribution of the amount of variation in dimension of the transcribed pattern, pattern dimensions of the photomask are measured, and the amount of variation in dimension of the transcribed pattern on the wafer is obtained by optical simulation using the pattern dimensions of the photomask.

5. The method according to claim 3, wherein the amount of variation in dimension of the transcribed pattern on the wafer is obtained from an optical image of the photomask pattern formed using an optical system equivalent to an exposure apparatus.

6. The method according to claim 3, wherein the distribution of the amount of variation in dimension is obtained as a contour graph in which points whose the amounts of variation in dimension are equal are connected with a line, and the region in which the amount of variation in dimension exceeds the allowable range is specified using the contours.

7. The method according to claim 6, wherein a region enclosed by one contour and a region put between two contours are subjected to the additional processing as a unit.

8. The method according to claim 1, wherein said additional processing comprising: photoresist being applied onto the photomask;
an opening being formed in the photoresist by partially removing the photoresist; and a glass portion of the photomask exposed to the opening being selectively excavated by using the photoresist as an etching mask.

9. The method according to claim 8, wherein the amount of excavation of the glass portion of the photomask is calculated in advance by three-dimensional mask rigorous electromagnetic field simulation.

10. A phase shift photomask wherein a thickness of a glass portion of the photomask is partially adjusted so that an amount of variation in dimension of a transcribed pattern of the photomask on a wafer is in an allowable range at all drawing regions of the photomask.

11. The phase shift photomask according to claim 10, wherein the thickness of the glass portion is adjusted by etching for removing the glass portion partially.

12. The phase shift photomask according to claim 10, wherein for obtaining the distribution of the amount of variation in dimension of the transcribed pattern, pattern dimensions of the photomask are measured, and the amount of variation in dimension of the transcribed pattern on the wafer is obtained by optical simulation using the pattern dimensions of the photomask.

13. The phase shift photomask according to claim 10, wherein the amount of variation in dimension of the transcribed pattern on the wafer is obtained from an optical image of the photomask pattern formed using an optical system equivalent to an exposure apparatus.
